(19) United States
(12) Patent Application Publication
(10) Pub. No.: US 2026/0305233 A1
(43) Pub. Date: Oct. 1, 2026

(54) LASER HEATING TO ADJUST SUBSTRATE WARPAGE

(71) Applicant: Applied Materials, Inc., Santa Clara, CA (US)

(72) Inventors: Wei-Sheng Lei, San Jose, CA (US); Michael Rice, Pleasanton, CA (US)

(21) Appl. No.: 19/094,652

(22) Filed: Mar. 28, 2025

(51) Int. Cl. H01L 21/67; B23K 26/40; B23K 26/53; B23K 101/40

(52) U.S. Cl. CPC H10P 72/0616; B23K 26/40; B23K 26/53; B23K 2101/40

(57) ABSTRACT

Embodiments described herein relate to a method that includes forming a dielectric layer over a backside surface of a substrate, where the backside surface is opposite from a device layer on the substrate, and mapping a distortion of the substrate. In an embodiment, the method further includes irradiating a portion of the dielectric layer with a laser to locally modify the dielectric layer, where the dielectric layer has a first modulus and a modified portion of the dielectric layer has a second modulus that is different than the first modulus.

### BACKGROUND

### 1) Field

Embodiments relate to the field of semiconductor manufacturing and, in particular, to systems and methods for improving substrate warpage through localized laser modification of a backside dielectric layer.

### 2) Description of Related Art

In some semiconductor manufacturing process flows, multiple thin film deposition and patterning cycles are implemented on a substrate, such as a silicon wafer or a silicon carbide substrate, to build functional devices. In many instances, the inclusion of multiple layers may result in the introduction of stresses in the substrate (e.g., thermal stresses, mechanical stresses, and/or the like). The stress induced into the substrate may result in significant substrate distortion (which may be asymmetrically distributed over the wafer and sometimes be referred to as substrate saddling or substrate warpage). Highly distorted substrates may result in chucking failure, since the chuck (e.g., an electrostatic chuck (ESC)) may not be able to apply a sufficient chucking force to keep the substrate flat during subsequent deposition and/or patterning processes.

### SUMMARY

Embodiments described herein relate to a method that includes forming a dielectric layer over a backside surface of a substrate, where the backside surface is opposite from a device layer on the substrate, and mapping a distortion of the substrate. In an embodiment, the method further includes irradiating a portion of the dielectric layer with a laser to locally modify the dielectric layer, where the dielectric layer has a first modulus and a modified portion of the dielectric layer has a second modulus that is different than the first modulus.

Embodiments described herein relate to a method that includes forming a dielectric layer over a backside surface of a substrate, where the backside surface is opposite from a device layer on the substrate, and mapping a distortion of the substrate. In an embodiment, the method further includes a forming a modified region of the dielectric layer with a laser, where the modified region of the dielectric layer reduces the distortion of the substrate.

Embodiments described herein relate to a method that includes forming a dielectric layer over a backside surface of a substrate, where the backside surface is opposite from a device layer on the substrate. In an embodiment, the method may further include mapping a first distortion of the substrate, where the first distortion exceeds a maximum distortion compatible with a chuck. In an embodiment, the method may further include forming a modified region of the dielectric layer with a laser heating process, where the modified region of the dielectric layer reduces the first distortion of the substrate to provide a substrate with a second distortion that is less than the maximum distortion compatible with the chuck. In an embodiment, the method may further include securing the substrate to the chuck.

### BRIEF DESCRIPTION OF THE DRAWINGS

FIG. 1A is a cross-sectional illustration of a warped substrate with a device layer over a surface of the substrate, in accordance with an embodiment.

FIG. 1B is a cross-sectional illustration of a warped substrate that is being secured to a chuck, in accordance with an embodiment.

FIG. 2A is a cross-sectional illustration of a warped substrate with a device layer and a warpage reduction layer on a backside of the substrate, in accordance with an embodiment.

FIG. 2B is a plan view illustration of the backside of the warped substrate that shows the warpage reduction layer, in accordance with an embodiment.

FIG. 2C is a cross-sectional illustration of the substrate after the warpage reduction layer is selectively treated with laser exposure to form modified regions in the warpage reduction layer to reduce the warpage of the substrate, in accordance with an embodiment.

FIG. 2D is a plan view illustration of the substrate that illustrates the modified regions of the warpage reduction layer, in accordance with an embodiment.

FIG. 3A is a cross-sectional illustration of a substrate with a device layer and a warpage reduction layer that is treated with a laser, in accordance with an embodiment.

FIG. 3B is a cross-sectional illustration of a substrate with a device layer on one surface and a barrier layer and a warpage reduction layer on an opposing surface, in accordance with an embodiment.

FIG. 4 is a schematic illustration of a laser writing system that may be used in order to selectively modify portions of the warpage reduction layer in order to provide a desired amount of warpage control, in accordance with an embodiment.

FIG. 5A is a cross-sectional illustration of a substrate with a first amount of warpage, in accordance with an embodiment.

FIG. 5B is a cross-sectional illustration of the substrate with a second amount of warpage, where the warpage is improved as a result of laser treatment of portions of a warpage reduction layer on the substrate, in accordance with an embodiment.

FIG. 6 is a flow diagram that depicts a process for reducing the warpage of a substrate through a laser irradiated warpage reduction layer, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include systems and methods for reducing substrate warpage through localized laser modification of a backside dielectric layer. In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, thermal and/or mechanical stresses that are induced in semiconductor substrates as a result of multi-layer deposition and/or patterning processes may result in significant substrate distortion. High levels of distortion or other warpage may lead to chucking failures since the chuck may not be able to apply a high enough chucking force to flatten the substrate during subsequent deposition and/or patterning processes.

Many efforts have been made to resolve the substrate distortion that can lead to chucking failures. One option is to design more advanced electrostatic chucks (ESC). However, this demands a large financial investment in order to design and implement such designs. An alternative approach is to reduce the substrate distortion to a level that is capable of being chucked by existing ESCs. In some instances, the distortion reduction may be obtained through the deposition of a dielectric layer (e.g., Si₃N₄) of a certain thickness on a backside of the substrate in order to provide an opposing distortion force that results in a net reduction of the substrate distortion.

However, blanket distortion mitigation layers may not be suitable for all applications. For example, substrate distortion may result in the formation of complex substrate geometries. As such, a blanket dielectric coating on the backside surface is not able to address local substrate distortion, which may be needed in some embodiments.

Accordingly, embodiments disclosed herein include a process for forming a dielectric distortion mitigation layer on a backside surface of the substrate. After the distortion mitigation layer is formed, selected regions of the dielectric distortion mitigation layer may be modified with a laser in order to locally modify the distortion of the substrate in order to address local substrate distortion. For example, a map of the distortion (e.g., an out-of-plane distortion (OPD) map) of the substrate may be formed with any suitable metrology process, such as ellipsometry, profilometry, or the like. The map of the distortion can be used to determine which areas of the dielectric distortion mitigation layer need to be modified in order to reduce the distortion of the substrate.

In an embodiment, the dielectric distortion mitigation layer may be modified with a laser. The laser may result in a mechanical and/or compositional change in the irradiated regions of the dielectric distortion mitigation layer. In some instances, the irradiated regions may not be ablated during the modification process. This prevents the generation of particles or the like, which may negatively impact processing of the device layers. In some instances, the laser irradiation may result in a modulus (e.g., an elastic modulus) of the irradiated regions changing compared to the unexposed regions. The difference in the modulus may result in a different amount of stress induced into the substrate over the irradiated regions. Therefore, the selective treatment can be used to locally modify the distortion of the substrate.

It is to be appreciated that the laser may also interact with the underlying substrate in some instances. Accordingly, the wavelength of the laser may be chosen so that the laser is substantially absorbed by the dielectric layer before reaching the substrate. A desired level of laser absorption in the dielectric layer may be provided through choice of material of the dielectric layer and/or selection of the wavelength of the laser. For example, the dielectric layer may comprise silicon and nitrogen with a stoichiometric ratio of silicon and nitrogen or a non-stoichiometric ratio of silicon and nitrogen.

In yet another embodiment, the irradiation of the substrate by the laser may be limited further by providing a barrier layer between the dielectric layer and the substrate. For example, the barrier layer may comprise a material that is tuned to be substantially opaque to the laser. In some instances, the barrier layer may comprise an amorphous carbon material or the like.

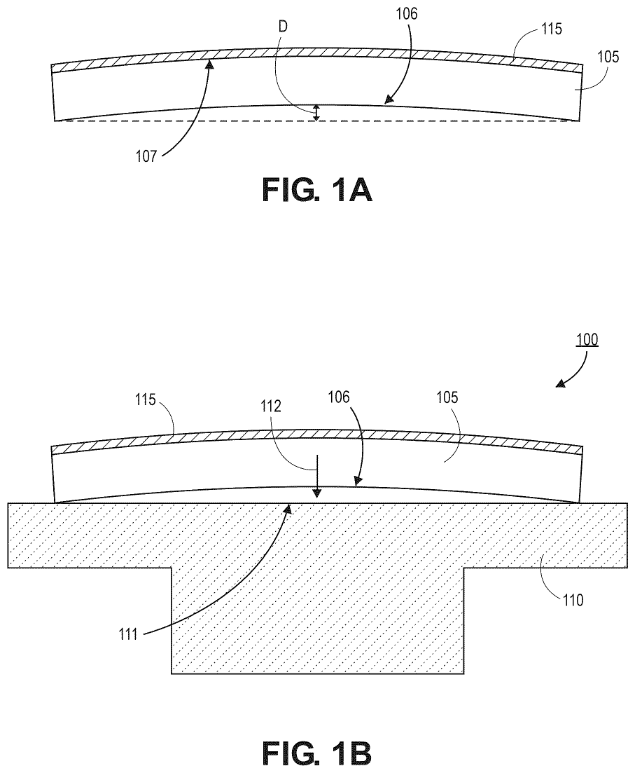

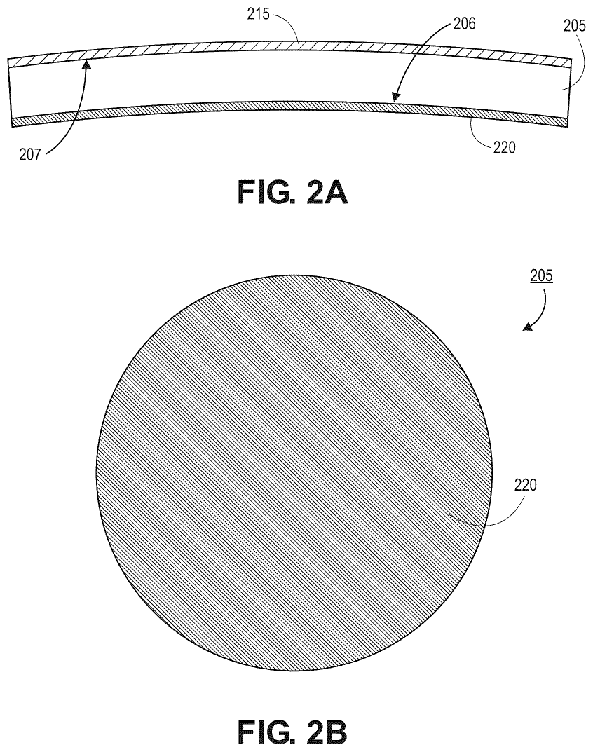

Referring now to FIG. 1A, a cross-sectional illustration of a substrate 105 is shown, in accordance with an embodiment. In an embodiment, the substrate 105 may be any type of substrate used in semiconductor manufacturing. For example, the substrate may be a silicon (Si) wafer, a silicon carbide (SiC) wafer, or the like. The substrate 105 may have any form factor, such as form factors common in semiconductor manufacturing (e.g., a 300 mm diameter wafer or any other common diameter wafer).

The substrate 105 may have a front surface 107 and a backside surface 106 that is opposite from the front surface 107. In an embodiment, a device layer 115 is formed over the front surface 107 of the substrate 105. The device layer 115 may comprise one or more layers that are provided in a stack in order to form a functional device on the substrate 105. For example, a plurality of layers that comprises the same material composition or different material compositions may be formed as part of the device layer 115. In an embodiment, one or more of the layers of the device layer 115 may be patterned (e.g., with an etching process or the like).

As noted above, the formation of a device layer 115 on the front surface 107 of the substrate 105 may result in the formation of distortion in the substrate 105. For example, thermal induced stresses (e.g., due to coefficient of thermal expansion (CTE) mismatch between the device layer 115 and the substrate 105) may result in warpage of the substrate 105. In the particular embodiment shown in FIG. 1A, the warpage is illustrated as a convex bowing of the front surface 107. The backside surface 106 may have a corresponding bow. For example, a distance between an apex of the backside surface 106 and a bottom of an outer edge of the substrate 105 along the backside surface 106 may have a distance D. The distance D may be approximately 300 μm or higher in some instances.

Referring now to FIG. 1B, a cross-sectional illustration of a portion of a processing tool 100 is shown, in accordance with an embodiment. In an embodiment, the processing tool 100 may comprise a chuck 110 that is within a chamber (not shown). The chuck 110 may be an any suitable chuck, such as an ESC, a vacuum chuck, or the like. The chuck 110 may generate a chucking force 112 (as indicated by the arrow) that secures the substrate 105 to a surface 111 of the chuck 110 in order to provide a substantially flat surface onto which additional layers may be deposited on the device layer 115 or so that patterning (e.g., etching, etc.) may be implemented on existing layers of the device layer 115.

As can be appreciated the ability to form a flat surface is important for providing good process uniformity. However, when the distortion is above a certain amount (e.g., above approximately 300 μm), the chucking force 112 may not be able to provide the desired flatness to the substrate 105. Alternatively, the chucking force 112 may be too high, which may cause damage to the substrate 105 and/or the device layer 115. That is, the chuck 110 may only be compatible with a given maximum distortion.

Accordingly, embodiments disclosed herein may include a process that includes forming a dielectric layer on the backside surface 106 of the substrate 105, and the dielectric layer may be selectively treated in order to accommodate complex distortion profiles of the substrate 105. For example, the dielectric layer may be treated by a laser that selectively heats portions of the dielectric layer deposited on the backside surface of the substrate 105 to precisely and selectively adjust and/or correct substrate distortion.

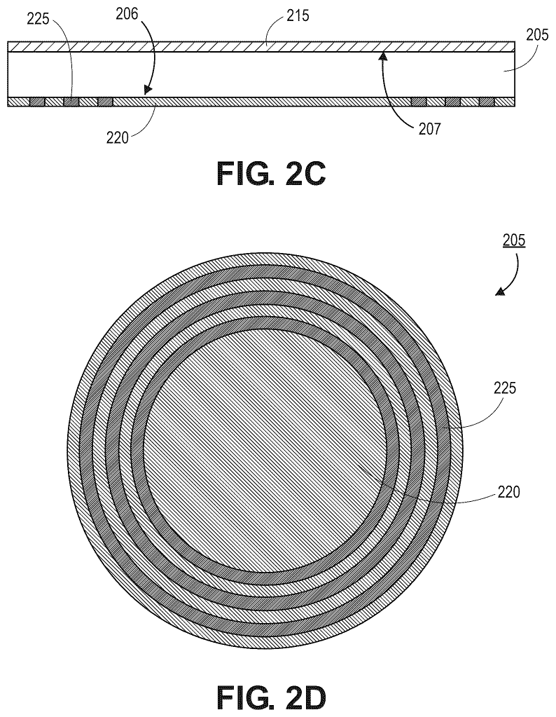

Referring now to FIG. 2A, a cross-sectional illustration of a substrate 205 is shown, in accordance with an embodiment. In an embodiment, the substrate 205 may comprise a front side surface 207 and a backside surface 206. In an embodiment, the substrate 205 may have a degree of distortion, as indicated by the curved front side surface 207 and the curved backside surface 206. While a single curve is shown in FIG. 2A, it is to be appreciated that the distortion of the substrate 205 may include any complex surface profile, such as a saddle, a bowl, a dome, an irregular warpage pattern, and/or the like.

In an embodiment, the substrate 205 may be similar to the substrate 105 described in greater detail above. For example, the substrate 205 may comprise a silicon substrate, a silicon carbide substrate, or the like. The substrate 205 may have a wafer form factor in some embodiments. In an embodiment, a device layer 215 may be formed over the front side surface 207 of the substrate 205. The device layer 215 may comprise one or more layers.

One or more of the layers of the device layer 215 may be patterned. In an embodiment, the device layer 215 may be similar to the device layer 115 described in greater detail above.

In an embodiment, a dielectric layer 220 may be formed over the backside surface 206 of the substrate 205. In an embodiment, the dielectric layer 220 may sometimes be referred to as a warpage reduction layer, a distortion reduction layer, or the like. While shown as a single monolithic layer, some embodiments may comprise a dielectric layer 220 that includes a plurality of layers with different material compositions. In a particular embodiment, the dielectric layer 220 may comprise silicon and nitrogen. A silicon nitride based dielectric layer 220 may be beneficial due to the capability of a silicon nitride layer to induce high amplitude stress into the substrate 205. In an embodiment, the dielectric layer 220 may have any suitable thickness. For example, a thickness of the dielectric layer may be between approximately 1.0 μm and approximately 10.0 μm. Though, thinner or thicker dielectric layers 220 may also be used in some embodiments.

In an embodiment, the dielectric layer 220 may comprise a stoichiometric ratio of elements. For example, in the case of a silicon nitride dielectric layer 220, the silicon nitride may have the form SiN_{X} where X is equal to approximately 1.33 (e.g., Si₃N₄). However, non-stoichiometric ratios of the elements may also be used. For example, in a silicon nitride dielectric layer 220 of the form SiN_{X}, X may be less than 1.33. Reducing the concentration of nitrogen in the dielectric layer 220 may reduce the modulus of the dielectric layer 220. However, altering the ratio of silicon to nitrogen may change a bandgap of the dielectric layer 220.

Altering the bandgap of the dielectric layer 220 may enable the use of longer wavelength (lower photon energy) lasers for the treatment process. For example, Si₃N₄ may have a bandgap of approximately 4.6 eV, whereas SiN has a bandgap of approximately 2.25 eV, and SiN_{0.67} has a bandgap of approximately 1.7 eV. As such, the longer wavelength lasers will still substantially absorb within the dielectric layer 220 instead of potentially damaging the underlying substrate 205 (e.g., with unwanted ablation and/or thermal damage). For example, silicon has a bandgap energy of approximately 1.12 eV, and 4H:SiC has a bandgap of approximately 3.25 eV. In this way a single dielectric layer 220 may be used without the need of an additional barrier layer to protect the substrate 205 from damage. Though, as will be described in greater detail herein, a barrier layer may also be used in some embodiments.

Referring now to FIG. 2B, a plan view illustration of the dielectric layer 220 on the backside surface 206 of the substrate 205 is shown, in accordance with an embodiment. As shown, the dielectric layer 220 may be a substantially uniform layer (e.g., a blanket layer) that is provided over the backside surface 206 of the substrate 205. In an embodiment, the dielectric layer 220 may be deposited on the substrate 205 with any suitable deposition process, such as a chemical vapor deposition (CVD) process, or the like.

Referring now to FIG. 2C, a cross-sectional illustration of the substrate 205 after the dielectric layer 220 is selectively treated is shown, in accordance with an embodiment. As shown, the treatment of the dielectric layer 220 may reduce the distortion of the substrate 205. In the illustrated embodiment, the distortion is substantially removed (e.g., the front side surface 207 and the backside surface 206 are substantially flat). Though, in other embodiments, the distortion reduction may reduce the distortion by an amount that allows the substrate 205 to be chucked by a chuck (such as chuck 110 described in greater detail above). For example, the distortion of the substrate 205 may be reduced to less than approximately 300 μm in some embodiments.

In an embodiment, the dielectric layer 220 may be treated with a laser in order to produced localized modified portions 225 of the dielectric layer 220. In an embodiment, the selection of the irradiated portions of the dielectric layer may be made after mapping the distortion of the substrate 205. The distortion may be mapped in order to provide an out of plane distortion (OPD) map. The substrate 205 may be mapped with any suitable metrology process, such as ellipsometry, profilometry, or the like.

Once the distortion is mapped, positions along the dielectric layer 220 that need to be modified are determined. For example, the modification implemented by laser irradiation may result in a change to the modulus in the modified portions 225. The change in modulus alters the amount of stress that is locally induced into the substrate 205 in order to provide a desired amount of warpage mitigation proximate to the modified portions 225.

In an embodiment, the laser irradiation may heat up the modified portions 225 in order to induce local stress and/or deformation redistribution. For example, the modulus may be altered by changing a composition of the dielectric layer 220 in the modified portions. For example, the heating may allow for hydrogen to escape the dielectric layer in the modified portions 225. That is, the modified portions 225 may have a lower concentration of hydrogen than the remaining portions of the dielectric layer 220 that were not exposed to the laser irradiation.

In an embodiment, the modified portions 225 of the dielectric layer 220 may be provided proximate to locations of the substrate 205 that have undergone more severe distortion than other regions of the substrate 205. In the example shown in FIG. 2C and the plan view illustration in FIG. 2D, the modified portions 225 are circular rings proximate to an edge of the substrate 205. However, it is to be appreciated that the modified portions 225 may comprise rings of any shape, lines of any shape, solid shapes (e.g., polygons, circles elliptical shapes, or the like).

It is to be appreciated that the laser irradiation process may result in substantially no ablation of the dielectric layer 220. That is, the laser irradiation may heat the dielectric layer 220 without the generation of substantially any particulates. This is beneficial for many semiconductor processing environments. For example, particles may redeposit on the device layer 215 and cause defects in the devices formed on the substrate 205. Additionally, the lack of particle generation allows for the distortion reduction process to be implemented without the need of subsequent cleaning processes to remove redeposited particles on the substrate 205.

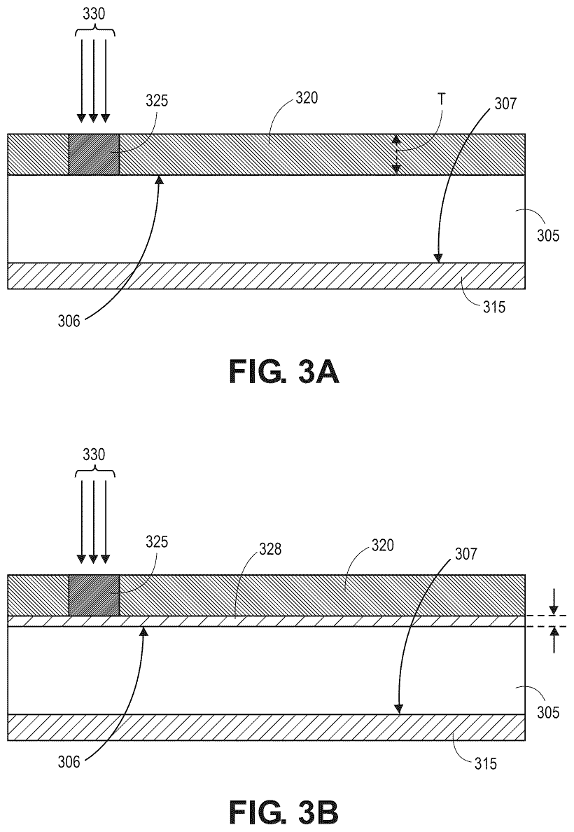

Referring now to FIG. 3A, a cross-sectional illustration of a substrate 305 that illustrates a laser irradiation process for the dielectric layer 320 is shown, in accordance with an embodiment. In an embodiment, the substrate 305 may be similar to any of the substrates described in greater detail herein. For example, the substrate 305 may be a silicon wafer or a silicon carbide wafer. The substrate 305 may comprise a front side surface 307 with a device layer 315 formed over the front side surface 307, and a backside surface 306 with the dielectric layer 320 formed over the backside surface 306. The device layer 315 may be similar to any of the device layers described herein, and the dielectric layer 320 may be similar to any of the dielectric layers described herein. For example, the dielectric layer 320 may comprise silicon and nitrogen with any suitable ratio between silicon and nitrogen, and the dielectric layer 320 may have a thickness T₁ that is between approximately 1 μm and approximately 10 μm.

As shown in FIG. 3A, the dielectric layer 320 may be exposed to laser irradiation 330. The laser irradiation 330 may result in the formation of modified portions 325 of the dielectric layer 320. The modified portions 325 may have been heated by the laser irradiation 330 in order to drive a compositional and/or structural change in the modified portions 325 that results in a change in the modulus of the modified portions 325 of the dielectric layer 320. For example, the heating induced by the laser irradiation 330 may result in the removal of some amount of hydrogen in the modified portions of the dielectric layer 320. In some embodiments, the laser beam is passed through a mask that is adopted to project the laser irradiation 330 with a certain width and length onto the dielectric layer 320 to heat the modified portion 325 of the dielectric layer 320.

In an embodiment, the type of laser chosen to treat the dielectric layer 320 may be based on the bandgap of the dielectric layer. In one embodiment, a 193 nm Excimer laser (with a photon energy of approximately 6.4 eV) may be used to irradiate the dielectric layer 320 since this wavelength may be substantially absorbed by a stoichiometric silicon nitride (Si₃N₄), or non-stoichiometric silicon nitride (SiN_{X}). However, such short wavelength lasers are generally expensive. As such, some embodiments may use less expensive lasers with longer wavelengths (e.g., 266 nm, 355 nm, or 532 nm are some alternative options). More generally, lasers with wavelengths up to approximately 550 nm may be used in some embodiments.

The longer wavelength lasers have lower photon energies (e.g., 4.66 eV for the 266 nm laser, 3.5 eV for the 355 nm laser, and 2.5 eV for the 532 nm laser). The lower photon energies may not be absorbed as fully by the stoichiometric ratio silicon nitride. As such, the backside surface 306 of the substrate 305 may be damaged by the laser irradiation 330. However, the non-stoichiometric silicon nitride formulations may provide better absorption of the laser irradiation 330 for the longer wavelength laser sources. As such, less expensive lasers may be used while still protecting the substrate 305 from damage due to the laser.

When improved protection of the substrate 305 is desired, a barrier layer may also be formed between the dielectric layer 320 and the substrate 305. An example of such an embodiment is shown in FIG. 3B. The substrate in FIG. 3B may be substantially similar to the substrate 305 in FIG. 3A, with the exception of the addition of a barrier layer 328 between the dielectric layer 320 and the backside surface 306 of the substrate 305. In an embodiment, the barrier layer 328 may have a thickness T₂ that is less than a thickness T₁ of the substrate 305. Depending on the material of the barrier layer 328, the thickness T₂ may be approximately 1.0 μm or less. For example, the thickness T₂ may be tens of nanometers or less.

In an embodiment, the barrier layer 328 may be a material with a bandgap that is lower than the bandgap of the dielectric layer 320 and/or lower than the bandgap of the substrate 305 may be used. In a particular embodiment, the barrier layer 328 may have a bandgap that is less than approximately 1.0 eV. In one embodiment, the barrier layer 328 may comprise an amorphous carbon material. Some amorphous carbon materials may have a bandgap that is approximately 0.3 eV or lower. Due to the small bandgap, the laser irradiation 330 is substantially absorbed (by a combination of the dielectric layer 320 and the barrier layer 328) before reaching the substrate 305. Accordingly, damage to the substrate 305 due to laser irradiation 330 is substantially eliminated.

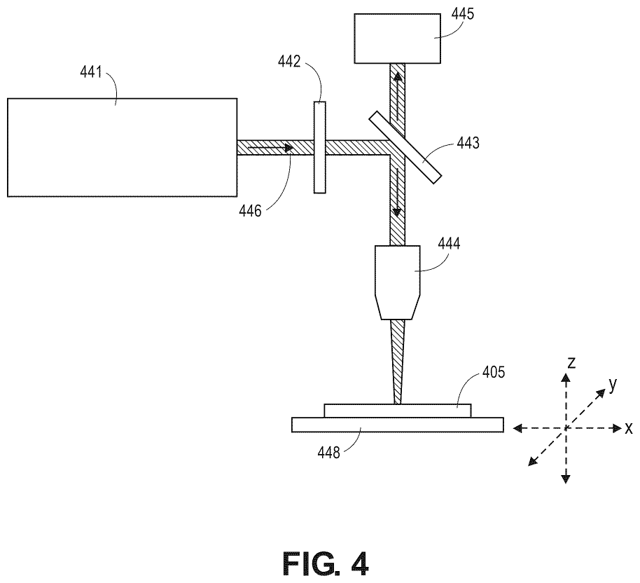

In an embodiment, the laser irradiation 330 may be provided to selected regions of the dielectric layer 320 by moving the substrate 305 relative to a stationary laser, moving the laser (and/or the laser beam) relative to a stationary substrate, or by moving both the substrate and the laser (and/or the laser beam). An example of a stationary laser and laser beam with a displaceable substrate is shown in FIG. 4.

Referring now to FIG. 4, a cross-sectional schematic illustration of a laser irradiation system is shown, in accordance with an embodiment. In an embodiment, the system may comprise a displaceable stage 448 that supports a substrate 405. In an embodiment, the substrate 405 may be similar to any of the substrates described in greater detail herein. For example, the substrate 405 may have a dielectric layer (not shown) that is irradiated in order to modify distortion of the substrate 405. In an embodiment, the stage 448 may be displaceable in one or more directions. For example, the stage 448 may be displaceable in one or more of the the X-direction, the Y-directions, and/or the Z-direction.

In an embodiment, the laser 441 may be similar to any of the lasers described herein. For example, the laser 441 may be an Excimer laser with a wavelength of 193 nm. Though, longer wavelength lasers (e.g. 248 nm Excimer laser) may also be used in some embodiments. In an embodiment, the laser 441 may emit a laser beam 446 that is propagated through a series of optics that direct the laser beam 446 to the substrate 405. The optics may include a shutter 442, a mirror 443 (e.g., a dichroic mirror), a focusing element 444 (e.g., a microscope or other focusing lens or lenses). In some instances, the mirror 443 may route a portion of the laser beam 446 towards an optical detector 445, such as a charge coupled device (CCD) sensor or other type of camera.

In FIG. 4, a fixed laser beam 446 system is shown. Other embodiments may include different ways to selectively modify the dielectric layer of the substrate 405. For example, a scanning laser beam with a galvo scanner or a polygon scanner (either with a stationary or moving stage) may also be used in order to selectively irradiate different portions of the dielectric layer.

The output laser beam 446 may pass through a patterned mask to project the laser beam onto wafer surface. For example, in the case of an Excimer laser, the laser beam 446 may be patterned into a linear shaped beam (e.g., approximately 5 μm wide and approximately 200 μm long), an array of linear shaped beams, or dot shaped beams to improve the laser processing efficiency and productivity. Typical laser heating process parameters that may be controlled during the processing in order to optimize the adjustment effect of substrate 405 distortion may include one or more of a laser power, a pulse energy, a pulse repetition frequency, a pulse width, a laser spot shape and/or profile and size, a scanning speed, a laser spot overlap, and a scanning line spacing.

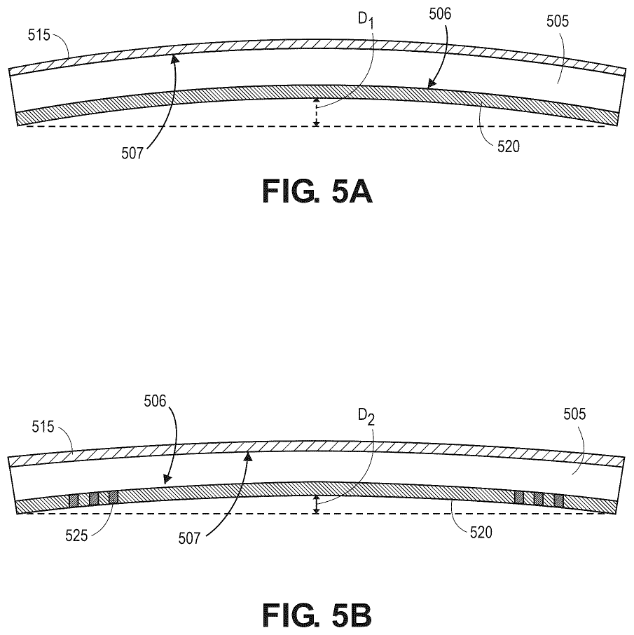

Referring now to FIGS. 5A and 5B, a pair of cross-sectional illustrations of a substrate 505 before and after selective laser irradiation of a dielectric layer 520 on the backside surface 506 of the substrate 505 is shown, in accordance with an embodiment. The substrate 505 may be similar to any of the substrates described in greater detail herein. In an embodiment, a device layer 515 may be provided over the front side surface 507 of the substrate 505. As shown, the substrate 505 may have a distortion (as indicated by the distortion D₁ in FIG. 5A). In an embodiment, the distortion D₁ may be above the maximum distortion compatible with a given chuck. For example, the distortion D₁ may be approximately 300 μm or more.

As shown in FIG. 5B, the dielectric layer 520 has been selectively irradiated by a laser to form modified regions 525. The modified regions 525 may be heated by the laser to modify a modulus of the modified regions 525. In an embodiment, the location of the modified regions 525 may be used to reduce the distortion. For example, the distortion D2 may be less than the distortion D1 shown in FIG. 5A. In an embodiment, the distortion D2 may be reduced so that the distortion is compatible with the given chuck. That is, the distortion correction provided by the laser irradiation treatment of the dielectric layer may at least reduce the distortion, even if the distortion is not completely removed.

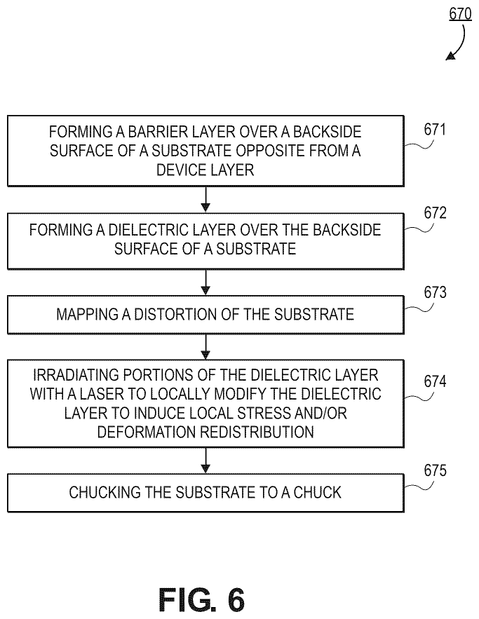

Referring now to FIG. 6, a flow diagram that depicts a process 670 for reducing the distortion of a substrate is shown, in accordance with an embodiment. In an embodiment, the substrate may be a silicon wafer or a silicon carbide substrate. The substrate may be similar to any of the substrates described in greater detail herein. In an embodiment, the process 670 may begin with operation 671, which comprises forming a barrier layer over a backside surface of the substrate opposite from a device layer. In an embodiment, the barrier layer may comprise a material with a bandgap that is lower than a bandgap of the substrate. For example, the barrier layer may comprise an amorphous carbon material. The barrier layer may be similar to any of the barrier layer materials described in greater detail herein.

In an embodiment, the process 670 may continue with operation 672, which comprises forming a dielectric layer over the backside surface of the substrate. In an embodiment, the dielectric layer may be provided over the barrier layer. In embodiments where a barrier layer is omitted, the dielectric layer may be formed directly on the backside surface of the substrate. The dielectric layer may comprise silicon and nitrogen. The silicon and nitrogen may be in a stoichiometric ratio or a non-stoichiometric ratio.

In an embodiment, the process 670 may continue with operation 673, which comprises mapping a distortion of the substrate. In an embodiment, the distortion may be mapped to form an OPD map. In an embodiment, the distortion may be mapped through ellipsometry, profilometry, or the like.

In an embodiment, the process 670 may continue with operation 674, which comprises irradiating portions of the dielectric layer with a laser to locally modify the dielectric layer to induce local stress and/or deformation redistribution. In an embodiment, the modified regions of the dielectric layer are heated by the laser irradiation in order to change a modulus of the modified region compared to the unexposed regions. In an embodiment, the laser may be an Excimer laser, such as a 193nm wavelength laser. Though, lasers with longer wavelengths may also be used in other embodiments. In an embodiment, the laser may be similar to any of the lasers described in greater detail herein.

In an embodiment, the process 670 may continue with operation 675, which comprises checking the substrate to a chuck. In an embodiment, the substrate may have the distortion reduced by the selective laser irradiation of operation 674. In an embodiment, the distortion of the substrate was reduced so that the chuck is capable of securing the substrate.

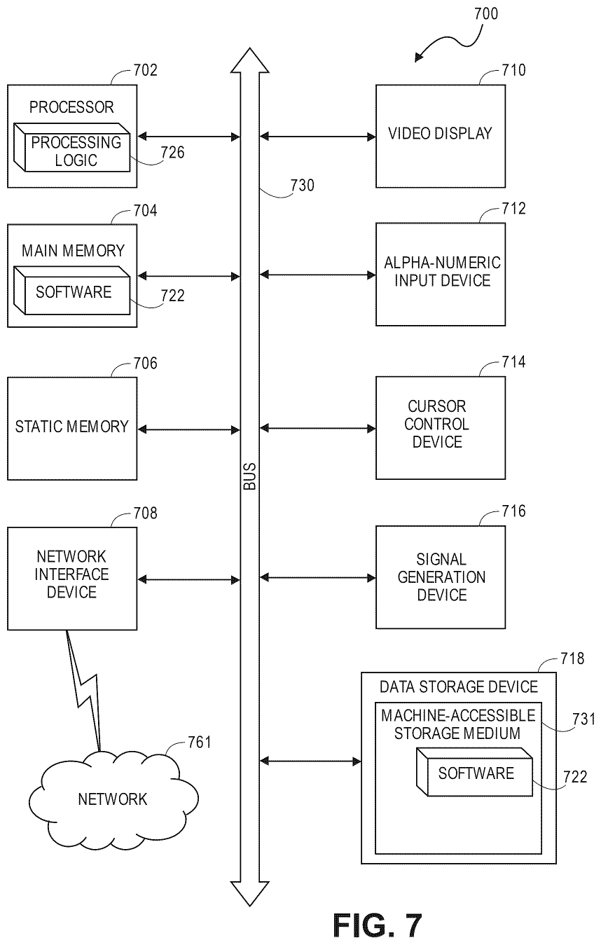

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming a dielectric layer over a backside surface of a substrate, wherein the backside surface is opposite from a device layer on the substrate;
mapping a distortion of the substrate; and
irradiating a portion of the dielectric layer with a laser to locally modify the dielectric layer, wherein the dielectric layer has a first modulus and a modified portion of the dielectric layer has a second modulus that is different than the first modulus.

2. The method of claim 1, wherein the dielectric layer comprises silicon and nitrogen.

3. The method of claim 2, wherein the dielectric layer comprises silicon and nitrogen with a stoichiometric ratio.

4. The method of claim 2, wherein the dielectric layer comprises silicon and nitrogen with a non-stoichiometric ratio.

5. The method of claim 1, wherein the laser comprises a wavelength that is less than 550 nm.

6. The method of claim 5, wherein the laser is a 193 nm Excimer laser.

7. The method of claim 1, further comprising:
forming a barrier layer between the dielectric layer and the substrate, wherein the barrier layer has a first bandgap and the substrate has a second bandgap, and wherein the first bandgap is smaller than the second bandgap.

8. The method of claim 7, wherein the barrier layer comprises an amorphous carbon layer.

9. The method of claim 1, wherein the distortion of the substrate is reduced after the modified portion of the dielectric layer is formed.

10. The method of claim 1, wherein the substrate comprises silicon or wherein the substrate comprises silicon and carbon.

11. A method, comprising:
forming a dielectric layer over a backside surface of a substrate, wherein the backside surface is opposite from a device layer on the substrate;
mapping a distortion of the substrate; and
forming a modified region of the dielectric layer with a laser, wherein the modified region of the dielectric layer reduces the distortion of the substrate.

12. The method of claim 11, wherein the dielectric layer comprises a first composition and the modified region of the dielectric layer comprises a second composition that is different than the first composition.

13. The method of claim 12, wherein the second composition comprise a lower amount of hydrogen than the first composition.

14. The method of claim 11, wherein the dielectric layer has a first modulus and the modified region of the dielectric layer comprises a second modulus that is different than the first modulus.

15. The method of claim 11, further comprising:
forming a barrier layer between the dielectric layer and the substrate.

16. The method of claim 15, wherein the barrier layer comprises a material that is substantially opaque to the laser.

17. The method of claim 11, wherein the substrate comprises silicon or wherein the substrate comprises silicon and carbon.

18. A method comprising:
forming a dielectric layer over a backside surface of a substrate, wherein the backside surface is opposite from a device layer on the substrate;
mapping a first distortion of the substrate, wherein the first distortion exceeds a maximum distortion compatible with a chuck;
forming a modified region of the dielectric layer with a laser heating process, wherein the modified region of the dielectric layer reduces the first distortion of the substrate to provide a substrate with a second distortion that is less than the maximum distortion compatible with the chuck; and
securing the substrate to the chuck.

19. The method of claim 18, wherein the substrate comprises silicon, or wherein the substrate comprises silicon and carbon.

20. The method of claim 18, further comprising:
forming a barrier layer between the dielectric layer and the substrate, wherein the barrier layer comprises amorphous carbon.
